(19) United States
(12) Patent Application Publication
(10) Pub. No.: US 2012/0154991 A1
(43) Pub. Date: Jun. 21, 2012

(54) CONNECTOR ADAPTOR OF ELECTRONIC DEVICE

(75) Inventor: CANHUO LEI, Shenzhen (CN)

(73) Assignee: SHENZHEN LIKKPOWER ELECTRONICS CO., LTD., SHENZHEN (CN)

(21) Appl. No.: 12/979,815

(22) Filed: Dec. 28, 2010

(30) Foreign Application Priority Data
Dec. 21, 2010 (CN) 201020671934.5

(51) Int. Cl. H05K 5/00

(52) U.S. Cl. 361/679.01

(57) ABSTRACT

This invention relates to a connector adaptor of an electronic device. In one embodiment, the connector adaptor comprises an outer frame for receiving and protecting the electronic device, wherein one side wall of the outer frame is internally provided with a plug which is in butt connection with a charging connector circuit of the electronic device; and one side wall of the outer frame is externally provided with a first USB interface for connecting with an external device through a data line to realize charging the electronic device.

### CROSS-REFERENCE TO RELATED APPLICATION

This application claims foreign priority benefits under 35 U.S.C. §119 from Chinese Patent Application Serial No. 201020671934.5, filed on Dec. 21, 2010, the content of which is incorporated herein by reference in its entirety.

### TECHNICAL FIELD

This invention relates to the technical field of electronics, in particular to a connector adaptor of an electronic device.

### BACKGROUND ART

With the continued development of electronic technology, electronic devices, especially digital mobile phones, cameras and the like, are popular generally and are upgraded frequently. Digital products are popular because its advanced technology brings convenience, rapidness and comfort to people.

The conventional digital products, such as mobile phones, mostly have rechargeable batteries which are charged by the chargers equipped for the products through the charging connectors on the mobile phones, wherein the charging connectors of the digital products vary according to different standards of different manufactures, and at present, the digital charging connectors on the markets have more than ten types. As the charging connectors of digital products have different standards, a user can not normally use the digital products if the electricity of the rechargeable battery equipped for the digital product is used up but the user forgets to carry the charger equipped or the use environment has no charging conditions (for example, when the use is going out) during the use of the digital product, thereby bringing convenience to the user.

In addition, the conventional digital products are further equipped with protective frames to prevent them from scratching or impacting by other objects, but some of the conventional protective frames are so cumbersome as to have influence on the shape of the digital products.

### CONTENT OF THE INVENTION

This invention is directed to providing a connector adaptor of an electronic device, which can protect the electronic device and facilitate the charging.

For achieving the above-mentioned purpose, this invention provides a connector adaptor of an electronic device, comprising an outer frame for receiving and protecting the electronic device, wherein one side wall of the outer frame is internally provided with a plug which is in butt connection with a charging connector circuit of the electronic device; one side wall of the outer frame is externally provided with a first USB interface for connecting with an external device through a data line to realize charging the electronic device.

Preferably, an external battery is further included; the external battery is embedded in the outer frame and is electrically connected with the outer frame through an electric-shock type connector; and the external battery is positioned above or below the electronic device.

Preferably, the external battery is in clamping buckle connection or fixedly connected with the outer frame.

Preferably, the external battery is plate-shaped; one side of the external battery is provided with a second USB interface for connecting with an external device through a data line to realize charging the external battery; and the second USB interface is exposed to the outer frame.

Preferably, the back face or the side of the external battery is provided with a lock catch for locking or unlocking the charging function of the external battery.

Preferably, the position of the upper end of the back of the external battery corresponding to a camera of the electronic device is provided with a camera hole for exposing the camera, and the lower end of the back of the external battery is provided with charging indicating lamps.

Preferably, the side corresponding positions of the periphery of the outer frame are respectively provided with prepared holes for exposing an earphone interface, an microphone interface, a volume adjusting button, a vibration sound adjusting button and/or an SIM card mounting hole of the electronic device; the position of the outer frame corresponding to a switch of the electronic device is provided with a switch button; and the upper end of the outer frame is provided with a playback hole.

Preferably, the switch button is arranged at one corner of the outer frame.

Preferably, the outer frame is in a hollow frame shape or groove shape.

Preferably, the electronic device comprises a mobile phone, a camera and/or a game machine.

The utility model provides a connector adaptor of an electronic device, which turns a charging connector of the electronic device into a standardized USB charging interface through arranging a USB interface electrically connected with the charging interface of the electronic device on an outer frame for protecting the electronic device and can realize charging the electronic device through connecting the standardized USB charging interface with an external device such as a computer host through a data line, thereby improving the charging convenience of the electronic device and solving the problem of charging difficulty of a consumer; and furthermore, the outer frame is internally provided with an external battery which can directly charge the electronic device through the outer frame, thereby further improving the charging convenience of the electronic device. In addition, the outer frame of the utility model can have multiple designs in shape according to the required styles of electronic devices and consumer groups, thereby meeting the needs of users for attractive shapes of digital products.

### BRIEF DESCRIPTION OF DRAWINGS

FIG. 1 is a stereoscopically structural schematic diagram of an embodiment of a connector adaptor of an electronic device of the utility model;

FIG. 2 is a front view of an embodiment of a connector adaptor of an electronic device of the utility model;

FIG. 3 is a top view of an embodiment of a connector adaptor of an electronic device of the utility model;

FIG. 4 is a bottom view of an embodiment of a connector adaptor of an electronic device of the utility model;

FIG. 5 is a left view of an embodiment of a connector adaptor of an electronic device of the utility model;

FIG. 6 is a right view of an embodiment of a connector adaptor of an electronic device of the utility model;

FIG. 7 is a back view of an embodiment of a connector adaptor of an electronic device of the utility model; and

FIG. 8 is a structural exploded view of an embodiment of a connector adaptor of an electronic device after the mounting of an outer frame, an external battery and an electronic device.

This invention is further explained in detail below in view of the figures.

### EMBODIMENTS

Through arranging a first USB interface which is electrically connected with a charging connector of the electronic device on an outer frame for protecting an electronic device so as to turn the charging connector of the electronic device into a standardized USB charging interface, solutions of embodiments of the utility model achieve the purposes of improving the charging convenience of the electronic device and solving the problem of charging difficulty.

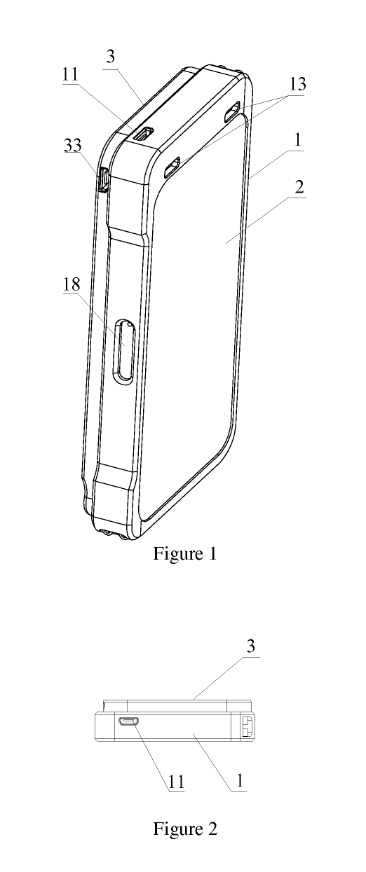

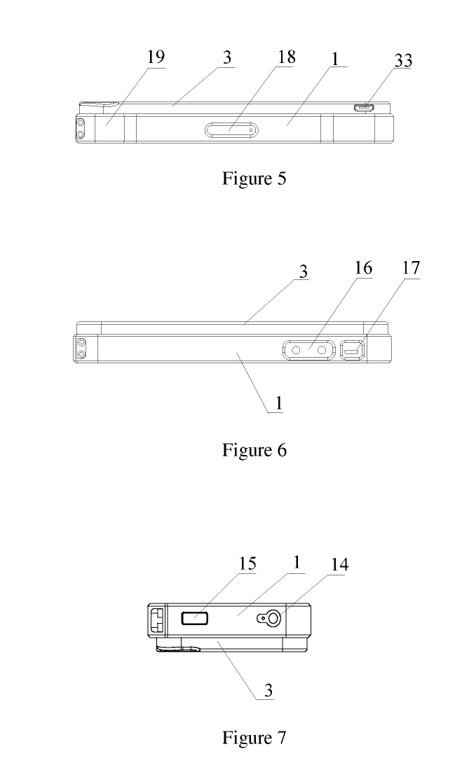

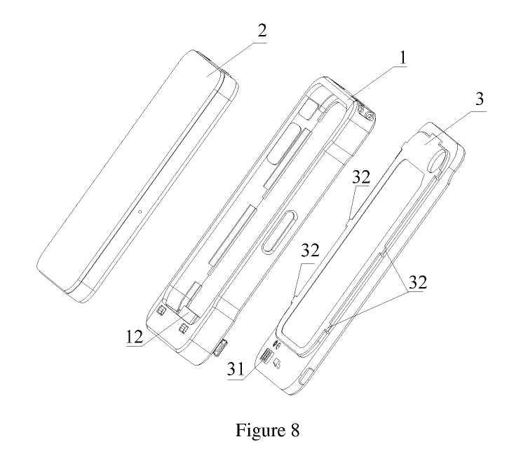

As shown in FIGS. 1-8, an embodiment of the utility model provides a connector adaptor of an electronic device, comprising an outer frame 1 for receiving and protecting an electronic device 2, wherein one side wall of the outer frame 1 is internally provided with a plug 12 which is in butt connection with a charging connector (not shown in Figures) circuit of the electronic device 2; one side wall of the outer frame 1 is externally provided with a first USB interface 11 for connecting with an external device through a data line to realize charging the electronic device 2. Therefore, charging connectors of different standards of various electronic devices 2 are turned into uniform standardized USB charging interfaces, a user can connect the first USB interface 11 of the outer frame 1 for assembling the electronic device 2 with an external device such as a computer host and charge the electronic device 2 through the external device only by a USB data line, thereby improving the charging convenience of the electronic device 2.

Furthermore, in the embodiment, for conveniently charging the electronic device 2, the connector adaptor further comprises an external battery 3; the external battery 3 is plate-shaped, and is embedded in the outer frame 1 and electrically connected with the outer frame 1 through an electric shock type connector 31 arranged on the external battery 3; the external battery 3 can be arranged above or below the electronic device 2. And therefore, when the environment where the electronic device 2 stays in is not suitable for charging or can not make charging through the external device, such as outdoor environment, the electronic device 2 can be charged through the external battery 3 equipped on the connector adaptor of an electronic device.

In the embodiment, the external battery 3 is in clamping buckle connection with the outer frame 1 through a clamping buckle 32 arranged at the periphery of the external battery 3; and in other embodiments, the external battery 3 is fixedly connected with the outer frame 1 through screws and the like.

As the external battery 3 and the outer frame 1 in the embodiment are in clamping buckle connection through the clamping buckle 32, the external battery 3 of the embodiment can be conveniently dismounted from the outer frame 1; and when the external battery 3 is not required for charging, the external battery 3 can be conveniently dismounted.

In another embodiment, the external battery 3 is provided with a lock catch 34 for locking or unlocking the charging function of the external battery 3; the lock catch in the embodiment has locking and unlocking positions, and can slide left and right; the charging function of the external battery 3 is locked through sliding the lock catch 34 to the locking position when the external battery lock 3 is not required for charging; and the charging function of the external battery 3 is unlocked through sliding the lock catch 34 to the unlocking position when external battery 3 is required for charging.

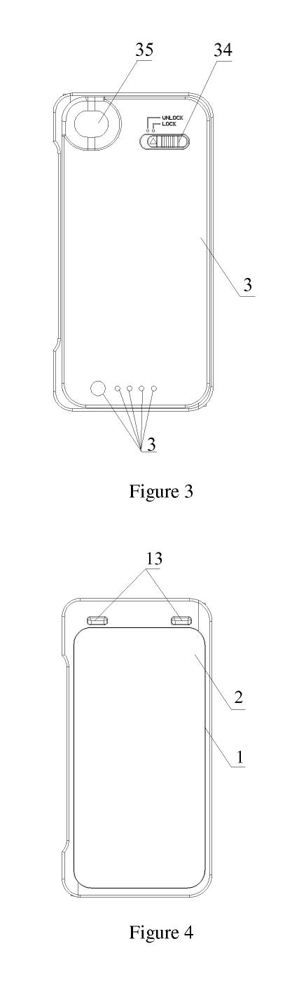

The lock catch 34 can be arranged at the back face or the sides of the periphery of the external battery 3. In the embodiment, the lock catch 34 is arranged at the back face of the external battery as shown in FIG. 3.

When the electricity of the external battery is used up, the external battery 3 needs charging; for conveniently charging the external battery 3, in the embodiment, one side of the external battery 3 is provided with a second USB interface 33 for connecting with an external device through a data line to realize charging the external battery 3; the second USB interface 33 is exposed to the outer frame 1 for conveniently connecting with the external device through the data line; the lower end of the back face of the external battery 3 is further provided with charging indicating lamps 36; and the charging indicating lamps 36 are charging state indicating lamps when the external battery 3 stays in the charging state, and are indicating lamps for indicating the electric quantity of the battery when the external battery 3 stays in the non-charging state. In the embodiment, there are 5 charging indicating lamps 36, and in other embodiments, the number of the charging indicating lamps 36 is determined according to actual requirements.

For matching with the normal use of various functions of the electronic device 2 received in the outer frame 1, in the embodiment, the corresponding positions of the outer frame and the external battery 3 are provided with corresponding prepared holes.

With iphone as the example, the position of the upper end of the Iphone is provided with a camera for shooting video or photographing, the periphery of a casing of the iphone is provided with an earphone interface, a microphone interface, a volume adjusting button, a vibration sound adjusting button, a switch button, an SIM card mounting hole and the like; for the normal working of the functions of various external interfaces or keys and the like of the electronic device 2 provided with the outer frame 1, in the embodiment, the position of the upper end of the back face of the external battery 3 corresponding to the camera of the electronic device 2 is provided with a camera hole 35 for exposing the camera, and the side corresponding positions of the periphery of the outer frame 1 are respectively provided with prepared holes for exposing the earphone interface 14, the microphone interface 15, the volume adjusting button 16, the vibration sound adjusting button 17 and/or the SIM card mounting hole of the electronic device 2. And the position of the outer frame 1 corresponding to a switch of the electronic device 2 is provided with a switch button 19, and in the embodiment, the switch button 19 is arranged at one corner of the outer frame 1.

Furthermore, for guaranteeing the normal volume of a receiver of the electronic device 2, in the embodiment, the position of the upper end of the outer frame 1 corresponding to the receiver of the electronic device 2 is provided with a playback hole 13.

It needs to be demonstrated that the number of the above-mentioned prepared holes or the keys and the corresponding positions on the outer frame 1 and the external battery 3 are correspondingly determined according to the actual structural characteristics of the electronic device 2, wherein the shape of the outer frame 1 can be hollow frame shape or groove shape, and can be coordinately determined according to the structural characteristics of the shape of the electronic device 2.

In addition, the electronic device 2 mentioned in the embodiment comprises a mobile phone, a camera, a game machine and the like.

Furthermore, the first USB interface 11 in the embodiment can further be used as a data interface, and data transmission or conversion can be made between the electronic device 2 and the external device such as a computer host through a data line, thereby further extending the data transmission function of the electronic device 2.

The connector adaptor of an electronic device of the embodiments of the invention is made innovation on the basis of the conventional protective frame, an outer frame of the connector adaptor of an electronic device is provided with a first USB interface electrically connected with a charging connector of the electronic device, and charging the electronic device through a common external device such as a computer host is realized through the first USB interface, irregular charging connectors of electronic devices are turned into uniform USB charging connectors without the limitations of the irregular charging connectors on charging by depending on a charger, thereby improving the charging convenience of the electronic device; and meanwhile, a mode of an external battery is added on the basis of the outer frame so as to further improve the charging convenience of the electronic device, the shape of the outer frame can be correspondingly determined according to the actual use requirements, and therefore the electronic device simultaneously has four functions of a protective frame, connector conversion, an external battery and attractive shape.

The above-mentioned is only preferred embodiments of the utility model, and shall not be regarded as limitations of the patent range of the utility model. All equivalent structures or flow transformations and modifications or direct or indirect applications in other related technical fields made according to the contents of the range of the specifications and figures of the utility model shall similarly fall into the patent range of the utility model.

What is claimed is:

1. A connector adaptor of an electronic device, comprising an outer frame for receiving and protecting the electronic device; one side wall of the outer frame is internally provided with a plug which is in butt connection with a charging connector circuit of the electronic device; and the side wall of the outer frame is externally provided with a first USB interface for connecting with an external device through a data line to realize charging the electronic device.

2. The connector adaptor of an electronic device as claimed in claim 1, further comprising an external battery; the external battery is embedded in the external battery and is electrically connected with the outer frame through an electric shock type connector arranged on the external battery; and the external battery is positioned above or below the electronic device.

3. The connector adaptor of an electronic device as claimed in claim 2, wherein the external battery and the outer frame are in clamping buckle connection or are fixedly connected through screws.

4. The connector adaptor of an electronic device as claimed in claim 3, wherein the external battery is plate-shaped; one side of the external battery is provided with a second USB interface for connecting with an external device through a data line to realize charging the external battery; and the second USB interface is exposed to the outer frame.

5. The connector adaptor of an electronic device as claimed in any of claims 2-4, wherein the back face or the side of the external battery is provided with a lock catch for locking or unlocking the charging function of the external battery.

6. The connector adaptor of an electronic device as claimed in any of claims 2-4, wherein the position of the upper end of the back face of the external battery corresponding to a camera of the electronic device is provided with a camera hole for exposing the camera; and the lower end of the back face of the external battery is provided with charging indicating lamps.

7. The connector adaptor of an electronic device as claimed in claim 6, wherein the side corresponding positions of the periphery of the outer frame are respectively provided with prepared holes for exposing an earphone interface, an microphone interface, a volume adjusting button, a vibration sound adjusting button and/or an SIM card mounting hole of the electronic device; the position of the outer frame corresponding to the position of a switch of the electronic device is provided with a switch button; and the upper end of the outer frame is provided with a playback hole.

8. The connector adaptor of an electronic device as claimed in claim 7, wherein the switch button is arranged at one corner of the outer frame.

9. The connector adaptor of an electronic device as claimed in claim 8, wherein the outer frame is in hollow frame shape or groove shape.

10. The connector adaptor of an electronic device as claimed in claim 9, wherein the electronic device comprises a mobile phone, a camera and/or a game machine.
